(19) United States
(12) Patent Application Publication
(10) Pub. No.: US 2012/0302043 A1
(43) Pub. Date: Nov. 29, 2012

(54) PROCESS FOR DECARBURIZATION OF A SILICON MELT

(76) Inventor: Jochen Hintermayer, Trostberg (DE)

(21) Appl. No.: 13/574,335

(22) PCT Filed: Dec. 27, 2010
(86) PCT No.: PCT/EP2010/070756

§ 371 Date: Jul. 20, 2012

(30) Foreign Application Priority Data
Jan. 21, 2010 (DE) 10 2010 001 094.4

(51) Int. Cl. H01L 21/322

(52) U.S. Cl. 438/476; 257/E21.321

(57) ABSTRACT

The present invention relates to a novel process for decarburizing a silicon melt, and to the use thereof for production of silicon, preferably solar silicon or semiconductor silicon.

The present invention relates to a novel process for decarburizing a silicon melt, and to the use thereof for production of silicon, preferably solar silicon or semiconductor silicon.

The production of silicon in a light arc furnace by reduction of silicon dioxide with carbon has been known for some time and is described in documents including DE 3 013 319 (Dow Corning). The silicon obtained, however, still contains about 1000 ppm of carbon when tapped off, which has to be lowered down to below 3 ppm by suitable aftertreatment/purification processes to produce solar silicon, in order that the solar cells produced therefrom have a high efficiency.

There have been descriptions of various processes in which the carbon content is lowered in a plurality of steps. One example is the Solsilc process (www.ecn.nl), in which a decarburization is carried out in a plurality of steps. This involves first cooling the tapped-off silicon under controlled conditions, in the course of which SiC particles separate out of the melt. These are then removed from the silicon in ceramic filters. Subsequently, the silicon is deoxidized with an argon-water vapour mixture. Finally, the prepurified, coarsely decarburized silicon is supplied to a directed solidification. However, the process described is costly and inconvenient since SiC particles separating out in the course of controlled cooling stick to the crucible wall. Moreover, the ceramic filters are frequently blocked by SiC particles. After the filtering has ended, crucible and filter have to be cleaned in laborious operations, for example by acid cleaning with hydrofluoric acid. Owing to the product properties of hydrofluoric acid, this step constitutes a considerable potential danger.

The directed solidification of a silicon block has likewise been described in detail in the report 03E-8434-A, Silicium für Solarzellen [Silicon for Solar Cells], Siemens AG, November 1990. This process can provide a carbon content of below 2 ppm in the silicon. However, a disadvantage of this process is that the directed solidification to remove carbon is very costly and time-consuming. A furnace cycle lasts two days and therefore requires an energy consumption of 10 kWh/kg of silicon. In addition, in this process, only 80% of the silicon block obtained after the directed solidification can be used for solar cells. The top, bottom and edge of the block have to be removed owing to very high carbon contents.

In alternative approaches, for example, DE 3883518 and JP2856839 have proposed blowing SiO₂ into the silicon melt. The SiO₂ added reacts with the carbon dissolved in the melt to form CO, which escapes from the silicon melt. A disadvantage of this process is that the SiC dissolved in the silicon melt does not react completely with the SiO₂. In addition, further raw material has to be introduced into the process in the form of the SiO₂, which increases the raw material costs.

Various modifications to this process have been described in JP02267110, JP6345416, JP4231316, DE 3403131 and JP2009120460. Disadvantages of these processes which have become known include caking on and blockages of plant parts.

There is therefore still an urgent need for an effective, simple and inexpensive process for decarburization of a silicon melt, obtained by carbothermic reduction of SiO₂.

It was therefore an object of the present invention to provide a novel process for decarburization of a silicon melt, which has the disadvantages of the prior art processes only to a reduced degree, if at all. In a specific object, the process according to the invention shall be employable for production of solar silicon and/or semiconductor silicon.

Further objects not specified explicitly are evident from the overall context of the description, examples and claims which follow.

The objects are achieved by the process described in detail in the description which follows, the examples and the claims.

The inventors have found that, surprisingly, it is possible in a simple, inexpensive and effective manner to decarburize a silicon melt when silicon monoxide (SiO) is blown into it.

The process is advantageous especially because the by-product obtained from the preparation of silicon by reaction of SiO₂ with C in a light arc furnace is about 0.6 kg of SiO per kilogram of silicon. This SiO can, in a preferred embodiment of the present invention, be collected, optionally freed of carbon, and used again for decarburization of the melt. Thus, both the raw material costs and the waste costs are lowered. In addition, the SiO has a very high purity, such that the process can be used for production of high-purity silicon.

As already mentioned, a silicon melt which originates from a light arc reduction furnace has a carbon content of about 1000 ppm. At a tapping temperature of 1800° C., the majority of this carbon is dissolved in the melt. If, however, the melt is cooled, for example to 1600° C., the result is that a large portion of the carbon precipitates out of the oversaturated melt as SiC. The carbon solubility in silicon as a function of temperature is described, according to Yanaba et al., Solubility of Carbon in liquid Silicon, Materials Transactions. JIM, Vol. 38, No. 11 (1997), pages 990 to 994, by

log C=3.63−9660/T

where the carbon content C is reported in percent by mass, and the temperature T in degrees Kelvin.

Table 1 below shows the relationship for a melt with 1000 ppm:

TABLE 1

| T [° C.] | C dissolved [ppm] | C in form of SiC [ppm] |
|---|---|---|
| 1800 | 933 | 67 |
| 1700 | 542 | 458 |
| 1600 | 297 | 703 |
| 1500 | 152 | 848 |

Table 1 shows the importance of a process in which the SiC is also removed effectively.

Without being bound to a particular theory, the inventors are of the view that, as a result of the addition of SiO, the dissolved carbon is removed from the silicon melt and, as a result, redissolution of the SiC takes place. If SiO is supplied to the silicon melt over a sufficient period or the process according to the invention is performed observing one or more hold time(s) in which the SiC can go back into solution, the process according to the invention can achieve very effective decarburization. In this context, it is a particular advantage of the present invention over the prior art processes that SiO is significantly more reactive than SiO₂. In the different embodiments thereof, the process according to the invention thus has the advantage that not only the carbon dissolved in the silicon melt but also the dissolved SiC can be removed effectively.

The present invention thus provides a process in which silicon monoxide is added to a silicon melt to reduce the carbon content of the melt.

The silicon monoxide can in principle be added in any state of matter. Preference is given, however, to using solid silicon monoxide, more preferably powder or granules. The mean particle size is preferably less than or equal to 1 mm, more preferably less than 500 μm and most preferably 1 to 100 μm. This silicon monoxide may originate from any source. In a specific embodiment, the silicon monoxide used is obtained as a by-product in silicon production and optionally freed of carbon fractions (referred to hereinafter as “SiO by-product”). Particular preference is given to collecting the SiO by-product and introducing it directly back into the silicon melt, so as to give rise to a closed circuit in a particularly preferred manner.

In a preferred embodiment of the present invention, the silicon monoxide, especially as a powder, is blown into the silicon melt by means of a gas stream, preferably a noble gas or inert gas stream, more preferably an argon, hydrogen, nitrogen or ammonia stream, most preferably an argon stream or a stream composed of a mixture of the aforementioned gases.

The SiO can be added at different points. For instance, SiO can be added to the silicon melt in the reduction reactor before it is tapped off. However, it is also possible to tap off the silicon and then to add the SiO to the silicon melt, for example in a melting crucible or a melting tank. Combinations of these process variants are likewise conceivable.

On addition of the silicon monoxide, the temperature of the melt should be between 1412° C. and 2000° C., preferably 1412° C. and 1800° C., more preferably between 1450° C. and 1750° C. According to the temperature, the contents of C and SiC in the silicon melt vary as shown in Table 1.

When the carbon in the melt is present in dissolved form, exclusively or at least substantially, i.e. to an extent of more than 95% by weight of the total carbon content, the addition of the silicon monoxide in a first preferred process variant is performed without interruption until a sufficiently low carbon content below 3 ppm is attained.

When a significant proportion of the carbon, i.e. more than 5% by weight of the total carbon content, is present in the form of SiC impurities, it is possible in a second preferred process variant to interrupt the addition of the SiO once or more than once and then to continue it again. Within the addition times, the addition of SiO removes the dissolved carbon from the melt, which gives rise to an undersaturated melt. Within the interruption times (hold times), SiC can dissolve again in the silicon melt. This again gives rise to dissolved carbon, which can subsequently be removed from the melt by renewed addition of SiO. Preference is given to performing one to 5 interruptions each of 1 min to 5 h, preferably 1 min to 2.5 h, more preferably 5 to 60 minutes. Particular preference is given to undertaking one interruption for the aforementioned period. Very particular preference is given to first adding SiO to the silicon melt and, after an addition time of 0.1 min to 1 hour, preferably 0.1 min to 30 min, more preferably 0.5 min to 15 min and especially preferably 1 min to 10 min, interrupting the addition for a duration (hold time) of 1 min to 5 h, preferably 1 min to 2.5 h, more preferably 5 to 60 minutes, in order to enable the dissolution of the SiC particles in the melt. After the end of the hold time, the addition of the SiO is restarted and continued until the desired low total carbon content, preferably less than or equal to 3 ppm, has been attained. Over the entire process duration, the temperature of the melt is preferably held within the abovementioned range.

It has been found to be particularly advantageous when the temperature of the melt is raised before the addition of the silicon monoxide has ended, preferably 1 to 30 min before, more preferably 1 to 10 min before, if it is lower beforehand, to greater than or equal to 1600° C., preferably 1650 to 1800° C., more preferably 1700 to 1750° C. This allows the equilibrium between carbon dissolved in the silicon and SiC to be shifted toward dissolved carbon.

The process according to the invention can additionally be made more effective by passing a bubble former through the melt or adding it to the melt. The bubble former used may be a gas or a gas-releasing substance. The bubble former multiplies the number of gas bubbles and improves the driving of the COₓ gases out of the melt. The gas passed through the melt may, for example, be a noble or inert gas, preferably a noble gas, hydrogen, nitrogen or ammonia gas, more preferably argon or nitrogen or a mixture of the aforementioned gases.

The gas-releasing substance, preferably a solid, is preferably added to the silicon monoxide, more preferably in a proportion by weight of 1% to 10% based on the mixture of silicon monoxide and gas former. A suitable agent for this purpose is ammonium carbonate powder because it decomposes to gases without residue when blown into the melt, and does not contaminate the melt.

Additionally preferably, a flow auxiliary can be added to the silicon monoxide, preferably a high-purity amorphous silicon dioxide, for example a high-purity fumed silica or precipitated silica or a high-purity silica gel. The proportion of the flow auxiliary is preferably up to 5% by weight, more preferably up to 2.5% by weight, even more preferably up to 2% by weight and especially preferably 0.5 to 1.5% by weight, based on the amount of silicon monoxide added.

The present invention also encompasses processes in which the addition of SiO to the silicon melt is preceded first by coarse decarburization, such that the total carbon content in the silicon melt is brought preferably below 500 ppm, more preferably below 250 ppm and especially preferably below 150 ppm before SiO is added. Suitable processes for coarse decarburization are known to those skilled in the art, for example cooling the melt to precipitate the SiC and filtering the melt. Oxidative pretreatment of the melt with suitable oxidizing agents, for example oxidizing agent-containing gases or addition of SiO₂.

The process according to the invention can be used to produce metallurgical silicon, but also to produce solar silicon or semiconductor silicon. A prerequisite for production of solar silicon or semiconductor silicon is that the reactants used, i.e. SiO₂, C and SiO, have appropriate purities.

Preferably, in the process for producing solar silicon and/or semiconductor silicon, the purified, pure or highly pure raw materials used, such as silicon monoxide, silicon dioxide and carbon, feature a content of:
a. aluminium less than or equal to 5 ppm, preferably between 5 ppm and 0.0001 ppt, especially between 3 ppm and 0.0001 ppt, preferably between 0.8 ppm and 0.0001 ppt, more preferably between 0.6 ppm and 0.0001 ppt, even better between 0.1 ppm and 0.0001 ppt, even more preferably between 0.01 ppm and 0.0001 ppt, even more preference being given to 1 ppb to 0.0001 ppt,
b. boron less than 10 ppm to 0.0001 ppt, especially in the range from 5 ppm to 0.0001 ppt, preferably in the range from 3 ppm to 0.0001 ppt or more preferably in the range from 10 ppb to 0.0001 ppt, even more preferably in the range from 1 ppb to 0.0001 ppt,
c. calcium less than or equal to 2 ppm, preferably between 2 ppm and 0.0001 ppt, especially between 0.3 ppm and 0.0001 ppt, preferably between 0.01 ppm and 0.0001 ppt, more preferably between 1 ppb and 0.0001 ppt,
d. iron less than or equal to 20 ppm, preferably between 10 ppm and 0.0001 ppt, especially between 0.6 ppm and 0.0001 ppt, preferably between 0.05 ppm and 0.0001 ppt, more preferably between 0.01 ppm and 0.0001 ppt and most preferably 1 ppb to 0.0001 ppt;
e. nickel less than or equal to 10 ppm, preferably between 5 ppm and 0.0001 ppt, especially between 0.5 ppm and 0.0001 ppt, preferably between 0.1 ppm and 0.0001 ppt, more preferably between 0.01 ppm and 0.0001 ppt and most preferably between 1 ppb and 0.0001 ppt,
f. phosphorus less than 10 ppm to 0.0001 ppt, preferably between 5 ppm and 0.0001 ppt, especially less than 3 ppm to 0.0001 ppt, preferably between 10 ppb and 0.0001 ppt and most preferably between 1 ppb and 0.0001 ppt,
g. titanium less than or equal to 2 ppm, preferably less than or equal to 1 ppm to 0.0001 ppt, especially between 0.6 ppm and 0.0001 ppt, preferably between 0.1 ppm and 0.0001 ppt, more preferably between 0.01 ppm and 0.0001 ppt and most preferably between 1 ppb and 0.0001 ppt,
h. zinc less than or equal to 3 ppm, preferably less than or equal to 1 ppm to 0.0001 ppt, especially between 0.3 ppm and 0.0001 ppt, preferably between 0.1 ppm and 0.0001 ppt, more preferably between 0.01 ppm and 0.0001 ppt and most preferably between 1 ppb and 0.0001 ppt,
   and which more preferably have a sum of the abovementioned impurities of less than 10 ppm, preferably less than 5 ppm, more preferably less than 4 ppm, even more preferably less than 3 ppm, especially preferably 0.5 to 3 ppm and very especially preferably 1 ppm to 3 ppm. For each element, a purity within the range of the detection limit may be the aim.

Solar silicon features a minimum silicon content of 99.999% by weight, and semiconductor silicon a minimum silicon content of 99.9999% by weight.

The process according to the invention can be incorporated as a component process into any metallurgical process for production of silicon, for example the process according to U.S. Pat. No. 4,247,528 or the Dow Corning process according to Dow Corning, “Solar Silicon via the Dow Corning Process”, Final Report, 1978; Technical Report of a NASA Sponsored project; NASA-CR 157418 or 15706; DOE/JPL-954559-78/5; ISSN: 0565-7059 or the process developed by Siemens, according to Aulich et al., “Solar-grade silicon prepared by carbothermic reduction of silica”; JPL Proceedings of the Flat-Plate Solar Array Project Workshop on Low-Cost Polysilicon for Terrestrial Photovoltaic Solar-Cell Applications, 02/1986, p 267-275 (see N86-26679 17-44). Likewise preferred is the incorporation of the process step into the processes according to DE 102008042502 or DE 102008042506.

### Test Methods

The determination of the abovementioned impurities is carried out by means of ICP-MS/OES (inductively coupled spectrometry—mass spectrometry/optical electron spectrometry) and AAS (atomic absorption spectroscopy).

The carbon content in the silicon or the silicon melt after cooling is determined by means of an LECO (CS 244 or CS 600) elemental analyser. This is done by weighing approx. 100 to 150 mg of silica into a ceramic crucible, providing it with combustion additives and heating under an oxygen stream in an induction oven. The sample material is covered with approx. 1 g of Lecocel II (powder of a tungsten-tin (10%) alloy) and about 0.7 g of iron filings. Subsequently, the crucible is closed with a lid. When the carbon content is in the low ppm range, the measurement accuracy is increased by increasing the starting weight of silicon to up to 500 mg. The starting weight of the additives remains unchanged. The operating instructions for the elemental analyser and the instructions from the manufacturer of Lecocel II should be noted.

The mean particle size of the pulverulent silicon monoxide is determined by means of laser diffraction. The use of laser diffraction for determination of particle size distributions of pulverulent solids is based on the phenomenon that particles scatter or diffract the light from a monochromatic laser beam with differing intensity patterns in all directions according to their size. The smaller the diameter of the irradiated particle, the greater are the scattering or diffraction angles of the monochromatic laser beam.

The sample is prepared and analysed with demineralized water as the dispersing liquid. Before the start of the analysis, the LS 230 laser diffractometer (from Beckman Coulter; measurement range: 0.04-2000 μm) and the liquid module (Small Volume Module Plus, 120 ml, from Beckman Coulter) is allowed to warm up for 2 h, and the module is rinsed three times with demineralized water.

In the instrument software of the LS 230 laser diffractometer, the following optical parameters which are relevant for an evaluation according to the Mie theory are stored in a .rfd file:

Refractive index of the dispersing liquid R.I. Real_{water}=1.332
Refractive index of the solid (sample material) Real_{SiO}=1.46

### Imaginary=0.1

Form factor=1

In addition, the following parameters relevant for the particle analysis should be set:

Measurement time=60 s
Number of measurements=1
Pump speed=75%

Depending on the sample characteristics, the sample can be added to the liquid module (Small Volume Module Plus) of the instrument directly as a pulverulent solid with the aid of a spatula or in suspended form by means of a 2 ml disposable pipette. When the sample concentration required for the analysis has been attained (optimum optical shadowing), the instrument software of the LS 230 laser diffractometer gives an “OK” message.

Ground silicon monoxide is dispersed by 60 s of ultrasonication by means of a Vibra Cell VCX 130 ultrasound processor from Sonics with a CV 181 ultrasound converter and 6 mm ultrasound tip at 70% amplitude with simultaneous pumped circulation in the liquid module. In the case of unground silicon monoxide, the dispersion is effected without ultrasonication by 60 s of pumped circulation in the liquid module.

The measurement is effected at room temperature. The instrument software uses the raw data, on the basis of the Mie theory, with the aid of the optical parameters stored beforehand (.rfd file), to calculate the volume distribution of the particle sizes and the d50 value (median).

ISO 13320 “Particle Size Analysis—Guide to Laser Diffraction Methods” describes the method of laser diffraction for determination of particle size distributions in detail.

In the case of granular silicon monoxide, the mean particle size is determined by means of screen residue analysis (Alpine).

This screen residue determination is an air jet screening process based on DIN ISO 8130-1 by means of an S 200 air jet screening instrument from Alpine. To determine the d50 of microgranules and granules, screens having a mesh size of >300 μm are also used for this purpose. In order to determine the d50, the screens must be selected such that they provide a particle size distribution from which the d50 can be determined. The graphical representation and evaluation is effected analogously to ISO 2591-1, Chapter 8.2.

The d50 is understood to mean the particle diameter in the cumulative particle size distribution at which 50% of the particles have a lower particle diameter than or the same particle diameter as the particles with the particle diameter of the d50.

The examples which follow illustrate the process according to the invention without restricting it in any way.

### EXAMPLE 1

10 kg of polysilicon were melted in a sintered SiC crucible and doped with 1.2 g of carbon (120 ppm). The temperature was then increased to 1600° C. After thermal equilibration, silicon monoxide powder having a particle size of <0.045 mm (from Merck) was blown into the melt by means of an argon stream. 4 g of powder per minute were used. Samples were taken after 3, 6, 9 and 12 minutes of blowing-in time. Table 2 below shows the carbon values determined:

TABLE 2

| Blowing-in time [min] | 0 | 3 | 6 | 9 | 12 |
|---|---|---|---|---|---|
| Carbon content [PPM] | 118 | 31 | 11 | 5 | 3 |

### EXAMPLE 2

The experiment for Example 1 was modified by raising the temperature of the melt to 1700° C. after 6 minutes. Table 3 below shows the carbon values determined:

TABLE 3

| Blowing-in time [min] | 0 | 3 | 6 | 9 | 12 |
|---|---|---|---|---|---|
| Temperature [° C.] | 1600 | 1600 | 1600 | 1700 | 1700 |
| Carbon content [PPM] | 116 | 32 | 12 | 4 | 2 |

### EXAMPLE 3

Immediately after being tapped off from a light arc furnace, silicon was solidified. The silicon contained 1120 ppm of carbon in dissolved form and in the form of SiC. 10 kg of this material were melted and the temperature was brought to 1700° C. Then silicon monoxide powder was blown in by means of argon as described in Example 1. After 6 minutes, the treatment was interrupted and the melt was kept at a temperature of 1700° C. for 30 min. Subsequently, silicon monoxide was blown in once again, in the course of which samples were taken after 3, 6, 9 and 12 minutes. Table 4 below shows the carbon values determined:

TABLE 4

| Total time [min] | 0 | 6 | 36 | 39 | 42 | 45 | 48 |
|---|---|---|---|---|---|---|---|
| Blowing-in time [min] | 0 | 6 | 6 | 9 | 12 | 15 | 18 |
| Hold time [min] | 0 | 0 | 30 | 30 | 30 | 30 | 30 |
| Carbon content [PPM] | 1120 | 580 | 576 | 117 | 36 | 13 | 5 |

### EXAMPLE 4

This experiment was carried out analogously to Experiment 3, except that 2% by weight of ammonium carbonate powder, based on the total mass of the mixture of SiO and bubble former, was added to the silicon monoxide powder. Table 5 below shows the carbon values determined:

TABLE 5

| Total time [min] | 0 | 6 | 36 | 39 | 42 | 45 | 48 |
|---|---|---|---|---|---|---|---|
| Blowing-in time [min] | 0 | 6 | 6 | 9 | 12 | 15 | 18 |
| Hold time [min] | 0 | 0 | 30 | 30 | 30 | 30 | 30 |
| Carbon content [PPM] | 1118 | 560 | 562 | 89 | 21 | 6 | 3 |

1. A process for decarburizing a silicon melt, wherein silicon monoxide is added to a silicon melt to reduce the carbon content of the melt.

2. The process according to claim 1, wherein the silicon monoxide is added in solid form.

3. The process according to claim 1, wherein the silicon monoxide is blown into the melt by means of a gas stream.

4. The process according to claim 1, wherein the silicon melt on addition of the silicon monoxide has a temperature of 1412° C. to 2000° C.

5. The process according to claim 1, wherein the temperature of the silicon melt before the addition of SiO has ended is greater than or equal to 1600° C.

6. The process according to claim 1, wherein the addition of the silicon monoxide is interrupted at least once for a period of 1 minute to 5 hours.

7. The process according to claim 6, wherein the addition of SiO is interrupted after an addition time of 0.1 minute to 1 hour, for a duration (hold time) of 1 minute to 5 hours.

8. The process according to claim 1, wherein the addition of silicon monoxide is continued until the total carbon content of the silicon melt is less than or equal to 3 ppm.

9. The process according to claim 1, wherein a bubble former is supplied to the silicon melt by introducing a gas.

10. A process for producing silicon by reduction of SiO₂ with carbon, wherein the decarburization of the silicon melt is performed by a process according to claim 1.

11. The process according to claim 10, wherein the silicon is solar silicon or semiconductor silicon.

12. The process according to claim 10, wherein the process comprises a step in which the addition of SiO to the silicon melt is first preceded by a coarse decarburization such that the total carbon content in the silicon melt is brought below 500 ppm.

13. The process according to claim 3, wherein the gas stream is a noble gas stream.

14. The process according to claim 9, wherein the gas is a noble gas.

15. The process according to claim 1, wherein the temperature of the silicon melt before the addition of SiO has ended is raised to greater than or equal to 1600° C.

16. The process according to claim 1, wherein a bubble former is introduced to the silicon melt by supplying a gas-forming substance.

17. The process according to claim 16, wherein the gas-forming substance is ammonium carbonate powder.

18. The process according to claim 10, wherein the silicon dioxide is high-purity silicon dioxide.

19. The process according to claim 10, wherein the carbon is high-purity carbon.

20. The process according to claim 10, wherein the silicon monoxide is high-purity silicon monoxide.
